(19) United States
(12) Patent Application Publication
(10) Pub. No.: US 2014/0283899 A1
(43) Pub. Date: Sep. 25, 2014

(54) FRAMELESS SOLAR MODULE HAVING A MODULE CARRIER AND METHOD FOR PRODUCING SAME

(71) Applicant: SAINT-GOBAIN GLASS FRANCE, COURBEVOIE (FR)

(72) Inventors: Robert Gass, Herzogenrath (DE); Dieter Kleyer, Wuerselen (DE)

(21) Appl. No.: 14/350,797

(22) PCT Filed: Nov. 21, 2012
(86) PCT No.: PCT/EP2012/073203

§ 371 Date: Apr. 9, 2014

(30) Foreign Application Priority Data
Nov. 30, 2011 (EP) 11191448.7

(51) Int. Cl. H01L 31/048; H01L 31/18

(52) U.S. Cl. CPC H01L 31/048; H01L 31/18
USPC 136/251; 438/57

(57) ABSTRACT

A frameless solar module having a substrate and a cover layer between which a layer structure for forming solar cells is located is described. At least one module carrier for reinforcing and/or supporting mounting of the solar module is fastened to a substrate surface facing away from the layer structure, the module carrier having at least one adhesive surface, which is adhered to the substrate surface by an adhesive layer made of a cured adhesive. The adhesive layer has one or a plurality of spacers which are designed to keep the adhesive surface at a specifiable minimum distance from the substrate surface when the adhesive of the adhesive layer is not cured. The spacers have different dimensions for maintaining the distance between the adhesive surface of the module carrier and the substrate surface. A method for producing a frameless solar module in which an adhesive layer made of a curable adhesive is applied to at least one adhesive surface of a module carrier and/or a substrate surface is also described.

Photovoltaic layer systems for the direct conversion of sunlight into electrical energy are well known. They are commonly referred to as “solar cells”, with the term “thin-film solar cells” referring to layer systems with small thicknesses of only a few microns that require (carrier) substrates for adequate mechanical stability. Known substrates include inorganic glass, plastics (polymers), or metals, in particular metal alloys, and can, depending on the respective layer thickness and the specific material properties, be implemented as rigid plates or flexible films.

In view of the technological handling quality and efficiency, thin-film solar cells with a semiconductor layer of amorphous, micromorphous, or polycrystalline silicon, cadmium telluride (CdTe), gallium-arsenide (GaAs), or a chalcopyrite compound, in particular copper-indium/gallium-disulfur/diselenide, abbreviated by the formula CuF(In,Ga)(S,Se)₂, have proved advantageous. In particular, copper-indium-diselenide (CuInSe₂ or CIS) is distinguished by a particularly high absorption coefficient due to its band gap adapted to the spectrum of sunlight.

Typically, with individual solar cells, it is only possible to obtain voltage levels of less than 1 volt. In order to obtain a technically useful output voltage, many solar cells are connected to one another serially in a solar module. For this, thin-film solar modules offer the particular advantage that the solar cells can already be serially connected in an integrated form during production of the films. Thin-film solar modules have already been described many times in the patent literature. Reference is made merely by way of example to the printed publications DE 4324318 C1 and EP 2200097 A1.

In practice, solar modules are mounted on the roofs of buildings (“on-roof mounting”) or form a part of the roof cladding (“in-roof mounting”). It is also known to use solar modules as façade or wall elements, in particular in the form of freestanding or self-supporting (carrier-free) glass structures.

The roof mounting of solar modules is usually done parallel to the roof on a module holder anchored on the roof or a roof substructure. Such a module holder conventionally includes a rail system of parallel support rails, for example, aluminum rails, that are fastened by means of steel anchors on tile roofs or screws on corrugated sheet roofs or trapezoidal sheet metal roofs.

It is common practice to provide the solar module with a module frame made of aluminum that effects, on the one hand, mechanical reinforcement and can, on the other, serve for the mounting of the solar module on the module holder.

In recent times, frameless solar modules that have reduced module weight and can be manufactured with reduced production costs have increasingly been produced. Usually, frameless solar modules are provided on their back side with reinforcement struts made of steel or aluminum that are adhesively bonded to the back side of module. Like the module frame, the reinforcement struts act reinforcingly and can serve for fastening the solar module on the module holder. In the trade, such reinforcement struts are frequently referred to as “backrails”. In the patent literature, backrails are, for example, described in the publications DE 102009057937 A1 and US 2009/020 5703 A1. The German utility model DE 202010003295 U1 presents a module carrier adhesively bonded on a solar module, wherein spacers are introduced into the adhesive composition. Such spacers are also known from the German patent application DE 10 2009 057937 A1.

In contrast, the object of the present invention consists in advantageously improving the production of frameless solar modules with reinforcement struts (backrails), wherein the solar modules should have particularly high quality with regard to the fastening of the reinforcement struts. In addition, the production should be simplified and the mounting costs should be reduced. These and other objects are accomplished according to the proposal of the invention by a solar module and a method for producing a frameless solar module with the characteristics of the coordinated claims. Advantageous embodiments of the invention are indicated by the characteristics of the subclaims.

According to the invention, a frameless solar module is presented that has a substrate and a cover between which a layer structure for forming solar cells is situated. The substrate and the cover layer are made, for example, of inorganic glass, polymers, or metal alloys and are, for example, implemented as rigid plates that are connected to each other in a so-called laminated pane structure.

The framework solar module is preferably a thin-film solar module with thin-film solar cells preferably serially connected in an integrated form. Typically, the layer structure comprises a back electrode layer and a front electrode layer, as well as an absorber. Preferably, the absorber comprises a semiconductor layer made of a chalcopyrite compound, which can be, for example, a semiconductor from the group copper-indium/gallium disulfur dischwefel/diselenide (Cu(In,Ga)(S,Se)₂), for example, copper-indium-diselenide (CuInSe₂ or CIS) or related compounds.

At least one module carrier for reinforcing and/or supporting mounting of the solar module on a stationarily anchored module holder (e.g., rail system) is fastened by adhesive bonding on the back substrate surface facing away from the layer structure. The module carrier is preferably a reinforcement strut that extends along the longitudinal sides of a rectangular (viewed from above) solar module. Usually, the module carrier is manufactured from a different material than the, for example, glass (carrier) substrate, with it typically being made from a metallic material, for example, aluminum or steel. The module carrier has at least one adhesive surface for fastening on the substrate, which is adhesively bonded to the back substrate surface by an adhesive layer made of a cured adhesive.

It is essential here that the adhesive layer include one or a plurality of spacers, which are in each case implemented to maintain the adhesive surface of the module carrier at a pre-specifiable minimum distance from the back substrate surface when the adhesive is not (yet) cured, when the module carrier is placed on the back substrate surface in order to bond the module carrier to the back substrate surface by means of the adhesive layer.

The solar module according to the invention thus enables, in a particularly advantageous manner, a technically relatively uncomplicated, highly versatile, economical fastening of at least one module carrier on the back substrate surface, wherein a pre-specifiable minimum distance between the adhesive surface of the module carrier and the back substrate surface can be maintained reliably and certainly by the spacers.

In practice, solar modules are frequently exposed to severe temperature fluctuations that can range, for example, from −30° C. to +60° C. Due to the usually different materials of the module carrier and the substrate, these temperature fluctuations are accompanied by different thermal expansions of these materials. This is, in particular, the case when the module carrier is made of a metal such as aluminum or steel and the substrate is made of glass. As a consequence, severe mechanical stresses can appear in the adhesive bonds if the module carrier is arranged so close to the back substrate surface that touching contact or at least a transfer of force occurs between the module carrier and the substrate surface due to thermal expansion.

It has been demonstrated that the adhesive bonding of module carriers to the substrate in industrial series production by means of curing adhesives is always associated with a certain variability with regard to the distance between the module carrier and the back substrate surface. The reason for this is the plastic malleability of the not (yet) cured adhesive at the time of bonding of the module carrier and the substrate. Until now, it has been difficult to reliably and certainly maintain a minimum distance between the module carriers and the substrate in industrial series production of solar modules.

According to the invention, by means of the spacers in the at least one adhesive layer, it can always be ensured that a pre-specifiable minimum distance between the at least one adhesive surface of the at least one module carrier and the back substrate surface is maintained even with not yet cured adhesive. The spacers have, for this purpose, a hardness that is greater than that of the not cured adhesive. When the adhesive has cured, the distance between the module carrier and the substrate is also fixed by the adhesive. If the minimum distance between the module carrier and the back substrate pre-specifiable by the spacers is adapted to the temperature-induced volume fluctuations of the materials, it can be guaranteed that the module carrier adhesively bonded onto the substrate is spaced away from the back substrate surface such that when the adhesive is cured, the temperature-induced volume fluctuations of the materials can be absorbed by the adhesive layer. Thus, increased wear of the adhesive bonds caused by the temperature-induced volume fluctuations can be effectively counteracted.

In one embodiment of the frameless solar module according to the invention, the at least one spacer in the adhesive layer is manufactured from a material whose hardness is less than the hardness of the material of the (carrier) substrate. By means of this measure, it is advantageously possible to avoid locally elevated loads (“point loads”) of the substrate due to the spacers, for example, when the module carrier is pressed against the substrate for its fastening.

For this purpose, the spacers are preferably made of an elastically malleable material, for example, plastic, which enables simple and economical production of the spacers, wherein damage to the substrate by point loads can be reliably and certainly avoided.

Preferably, the elastically malleable spacers have a hardness that is in fact greater than that of the not cured adhesive, in order to maintain the pre-specifiable minimum distance between the module holder and the substrate when the adhesive is not cured, but corresponds to the maximum of the hardness of the cured adhesive such that after the adhesive is cured, no point loads appear. This can be of importance for the practical application of solar modules, in particular when high loads appear on the module carriers, for example, from snow or wind pressure loads. For example, in the case of a glass substrate, the elastically malleable spacers are, for this purpose, made of a material that has a Shore hardness in the range from 60 to 90 Shore, in particular in the range from 80 to 90 Shore.

The spacers can, in principle, have any shape suitable for the desired function, being implemented according to a preferred embodiment of the invention in a spherical shape in each case, which brings with it, in particular, process technology advantages and enables a simple and precise adjustment of the minimum distance by means of the spherical diameter.

The spacers can have a mutually equal dimension in the direction of the distance between the module carrier and the back substrate surface, for example, an equal spherical diameter. According to the invention, the spacers have a mutually different dimension (or different dimensions) in the direction of the distance between the module carrier and the back substrate surface for adjustment of the minimum distance between the module carrier and the back substrate surface, for example, different spherical diameters, by means of which the local minimum distance between the module carrier and the substrate is selectively adaptable to the special requirements of the module carrier and/or the substrate (e.g., geometry of the module carrier). If, for example, the geometry of the module carrier is different, the risk of a point load due to extremely compressed spacers is significantly reduced by this measure—in contrast to the case of an equal dimension of the spacers. In fact, elastically malleable spacers (for example, rubber balls) are usually only compressible up to a certain maximum thrust. If this “maximum thrust” is reached, they act as relatively hard bodies such that a point load cannot be ruled out.

In another advantageous embodiment of the solar module according to the invention, which is implemented in a rectangular shape, the at least one module carrier extends, for example, in the form of an elongated reinforcement strut along the (module) longitudinal sides and the at least one adhesive layer is implemented in the form of an adhesive bead extending similarly along the (module) longitudinal sides. Since solar modules are typically moved along the longitudinal sides in production lines of industrial series production, by means of this measure, a lateral displacement of the spacer (in the transverse direction of the module) can be advantageously avoided. A movement of the spacers out of the adhesive bead by movement of the solar modules can thus be reliably and certainly avoided.

Preferably, the solar module includes two module carriers, for example, elongated reinforcement struts, extending in the longitudinal direction, which are arranged on both sides of a longitudinal median plane arranged perpendicular to the substrate, with the module carriers adhesively bonded to the back substrate surface in each case by at least one adhesive bead extending in the longitudinal direction, and with each adhesive bead containing at least two spacers, which are situated on both sides of a transverse median plane arranged perpendicular to the substrate and perpendicular to the longitudinal median plane. This measure enables an economical, reliable, and certain distancing of the module carrier from the substrate.

The invention further extends to a method for producing a frameless solar module, in particular a thin-film solar module that comprises the following steps:
providing a substrate and a cover layer, between which is situated a layer structure for forming solar cells,
providing at least one module carrier for reinforcing and/or supporting mounting of the solar module,
applying an adhesive layer made of a curable adhesive on at least one adhesive surface of the module carrier and/or a substrate surface facing away from the layer structure,
introducing one or a plurality of spacers in the not yet cured adhesive, with the spacers implemented in each case to maintain the adhesive surface at a pre-specifiable minimum distance from the substrate surface when the adhesive of the adhesive layer is not cured,
bonding the module carrier to the substrate surface by means of the at least one adhesive layer,
(allowing) curing of the adhesive of the adhesive layer for the adhesive fastening of the module carrier on the substrate.

The spacers can have mutually different dimensions for maintaining the distance between the adhesive surface of the module carrier and substrate surface.

By means of the method according to the invention, a solar module can be produced technically simply and economically, wherein it is guaranteed that the module carriers are arranged at a minimum distance pre-specifiable by the spacers from the back substrate surface. From a process technology standpoint, it can be advantageous for the spacers to be introduced into the at least one adhesive layer already applied on the adhesive surface of the module carrier and/or the back substrate surface. This measure enables a simple spraying or injection of the adhesive from a conventional nozzle, with the nozzle not having to be adapted to the dimensions of the spacers. According to the invention, the introducing of the spacers into the adhesive layer occurs in that the spacers are pneumatically blown in by a pressure surge, which is technically realizable in a particularly simple and economic manner. In addition, the spacers can be selectively positioned at pre-specifiable locations within the adhesive layer. Moreover, differently dimensioned spacers can be introduced into the adhesive layer in a simple manner.

In another advantageous embodiment of the method according to the invention for producing a frameless rectangular solar module, the at least one module carrier extends along the (module) longitudinal sides and the at least one adhesive layer is implemented in the form of an adhesive bead extending along the longitudinal sides such that with the customary direction of movement of the solar modules, a lateral displacement of the spacers is avoided.

Preferably, two module carrier extending in the longitudinal direction are fastened on the back substrate surface on both sides of a longitudinal median plane perpendicular to the substrate, with the module carriers adhesively bonded in each case to the back substrate surface by at least one adhesive bead extending in the longitudinal direction, with at least two spacers introduced into the adhesive bead, which spacers are situated on both sides of a transverse median plane arranged perpendicular to the substrate and perpendicular to the longitudinal median plane.

The method according to the invention can serve in particular for producing a solar module of the invention implemented as described above.

The invention further extends to the use of at least one adhesive layer made of a curable adhesive for fastening a module carrier on a back substrate surface of a frameless solar module, in particular a thin-film solar module, wherein the adhesive layer contains one or a plurality of spacers that are in each case implemented to distance the module carrier with the not cured adhesive at a pre-specifiable minimum distance from the back substrate surface when the module carrier is pressed against the rear substrate surface. In this case the spacers have mutually different dimensions for maintaining the distance between the adhesive surface of the module carrier and the substrate surface.

The above-mentioned embodiments of the solar module and the claimed method for producing a solar module can be realized alone or in any combinations.

### BRIEF DESCRIPTION OF THE DRAWINGS

The invention is now explained in detail with the help of an exemplary embodiment, referring to the accompanying figures. They depict:

FIG. 1 using a schematic (partial) cross-sectional representation, the adhesive bonding of a reinforcement strut to the back substrate surface of the solar module;

FIG. 2 a schematic cross-sectional representation to illustrate the blowing of spheres into the adhesive bead for fastening the reinforcement strut of FIG. 1;

FIG. 3A-3B schematic perspective views of the reinforcement strut of the solar module of FIG. 1;

FIG. 4 a schematic plan view of the back of the solar module of FIG. 1;

FIG. 5 a schematic cross-sectional representation through the thin-film solar module of FIG. 1.

### DETAILED DESCRIPTION OF THE DRAWINGS

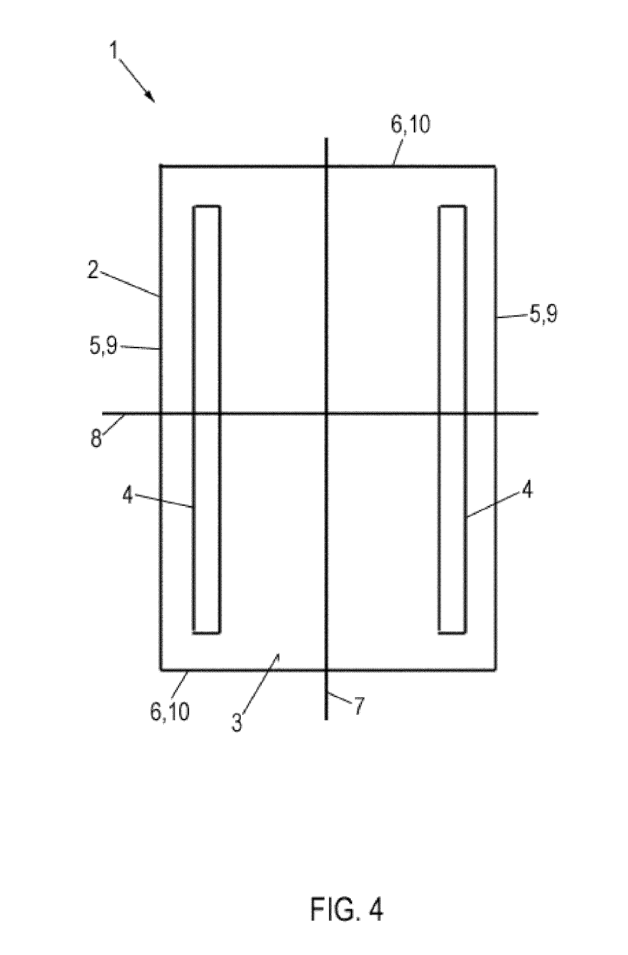

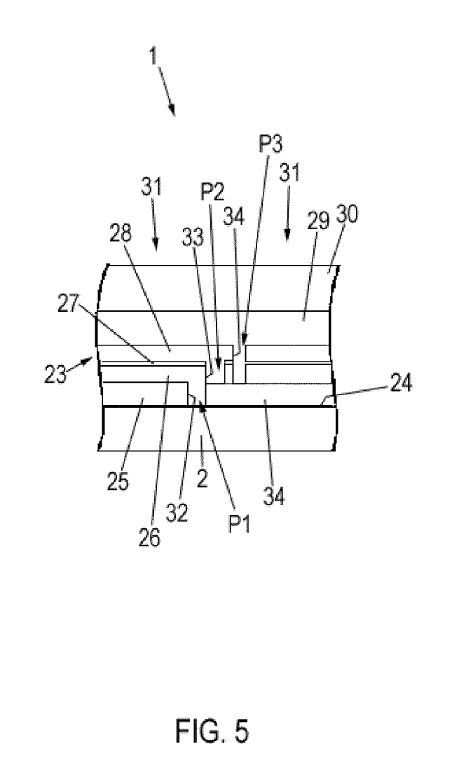

Reference is first made to FIGS. 4 and 5. FIG. 4 depicts a schematic view of the back side of the module (“side IV”) of a frameless thin-film solar module 1, referred to as a whole by the reference character 1. As is customary, the solar module 1 is implemented in the form of a flat rectangular body viewed from above with two parallel longitudinal sides 5 and transverse sides 6 perpendicular thereto. FIG. 5 depicts a cross-sectional view through the thin-film solar module 1.

As discernible in FIG. 5, the thin-film solar module 1 has a structure corresponding to the so-called “substrate configuration”, i.e., it has an electrically insulating (carrier) substrate 2 with a layer structure 23 made of thin layers applied thereon, which is arranged on a light-entry or front substrate surface 24 (“side III”) of the substrate 2. The substrate 2 is made here, for example, of glass with a relatively low light transmittance, with it equally possible to use other insulating materials with sufficient strength as well as inert behavior relative to the process steps performed.

Specifically, the layer structure 23 comprises a back electrode layer 25 arranged on the front substrate surface 24, which layer 25 is made, for example, of an opaque metal such as molybdenum (Mo) and can, for example, be applied on the substrate 2 by vapor deposition. The back electrode layer 25 has, for example, a layer thickness of ca. 1 μm. A semiconductor layer 26 that contains a semiconductor whose band gap is preferably capable of absorbing the greatest possible fraction of sunlight is deposited on the back electrode layer 25. The semiconductor layer 26 is made, for example, of a p-conductive chalcopyrite semiconductor, for example, a compound of the group Cu(In,Ga)(S,Se)₂, in particular sodium (Na)-doped copper-indium-diselenide (CInSe₂). The semiconductor layer 26 has, for example, a layer thickness, which is in the range from 1-5 μm and is, for example, ca. 2 μm. A buffer layer 27 is deposited on the semiconductor layer 26; which buffer layer 27 is made here, for example, of a single layer of cadmium sulfide (CdS) and a single layer of intrinsic zinc oxide (i-ZnO) (not shown in detail in the figures). The buffer layer 27 has, for example, a lower layer thickness than the semiconductor layer 26. A front electrode layer 28 is applied on the buffer layer 27, for example, by vapor deposition. The front electrode layer 28 is transparent to radiation in the visible spectral range (“window layer”), to ensure only slight weakening of the incident sunlight. The transparent front electrode layer 28, which can generally be referred to as a TCO-Schicht (TCO=transparent conductive electrode), is based on a doped metal oxide, for example, n-conductive, aluminum (Al)-doped zinc oxide (ZnO). The front electrode layer 28, together with the buffer layer 27 and the semiconductor layer 26, forms a heterojunction (i.e., a sequence of layers with opposing conductor type). The layer thickness of the front electrode layer 28 is, for example, ca. 300 nm.

For protection against environmental influences, a plastic layer 29 which is made, for example, of polyvinyl butyral (PVB) or ethylene vinyl acetate (EVA) and which is adhesively bonded to a cover plate 30 transparent to sunlight, which is, for example, made of low-iron extra-white glass is applied on the front electrode layer 28.

In order to increase the overall module voltage, the module surface of the thin-film solar module 1 is divided into a large number of individual solar cells 31, which are connected to each other in series connection. For this purpose, the layer structure 23 is patterned using a suitable patterning technology, for example, laser writing or machining (e.g., drossing or scratching). For each solar cell 31, such patterning typically comprises three patterning steps, abbreviated with the acronyms P1, P2, P3. In a first patterning step P1, the back electrode layer 25 is interrupted by the creation of a first trench 32, which is done before the application of the semiconductor layer 26, such that the first trench 32 is filled by the semiconductor material of this step. In a second patterning step P2, the semiconductor layer 26 and the buffer layer 27 are interrupted by the creation of a second trench 33, which is done before the application of the front electrode layer 28, such that the second trench 33 is filled by the electrically conducting material of this layer. In a third patterning step P3, the front electrode layer 28, the buffer layer 27, and the semiconductor layer 26 are interrupted by the creation of the third trench 34, which is done before the application of the plastic layer 29, such that the third trench 34 is filled by the insulating material of this layer. Alternatively, it would be conceivable for the third trench 34 to reach all way down to the substrate 2. By means of the patterning steps P1, P2, P3 described, solar cells 31 are formed serially connected to each other.

As discernible in FIG. 4, two elongated reinforcement struts 4 (referred to in the introduction to the description as “module carriers”) are fastened on the back side of the module or the back substrate surface 3 of the substrate 2, which faces away from the layer structure for forming the solar cells. The reinforcement struts 4 extend in each case along the longitudinal sides 5 of the solar module 1 and are arranged on both sides of a longitudinal median plane 7 of the solar module 1 near the longitudinal edge 9 of the module and end in each case a short distance from the transverse edge 10 of the module.

A mechanical reinforcement of the solar module 1 can be achieved by means of the two elongated reinforcement struts 4. On the other hand, the reinforcement struts 4 serve for mounting of the solar module 1 by fastening to a module holder, stationarily anchored, for example, on the roof or a roof substructure, which typically includes a plurality of support rails made, for example, of aluminum. The two reinforcement struts 4 are made of a metallic material, for example, aluminum or steel. Although two reinforcement struts 4 are depicted in FIG. 4, it is understood that the solar module 1 can equally have a larger or smaller number of reinforcement struts 4.

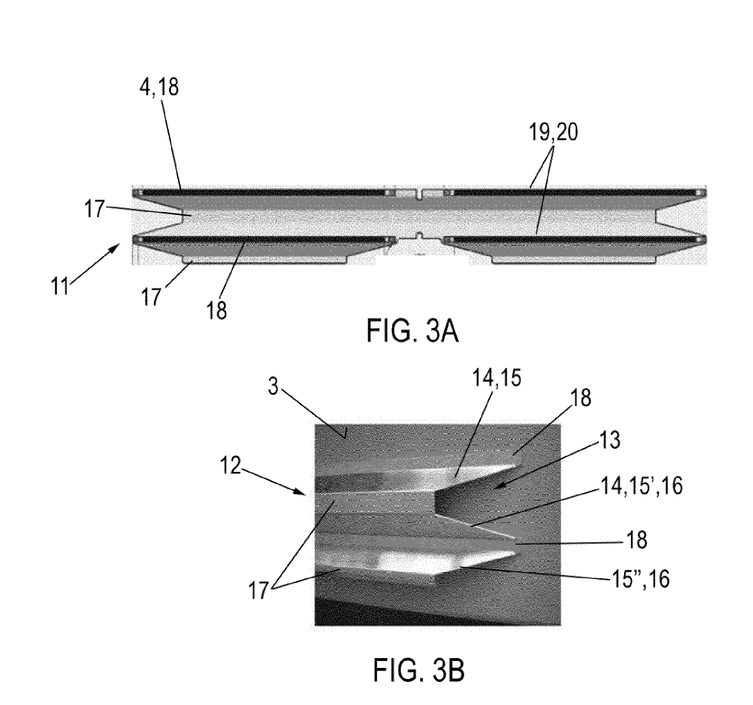

FIGS. 3A and 3B depict an individual reinforcement strut 4 in detail, with FIG. 3A depicting a perspective plan view of the front 11 of the reinforcement strut 4 to be bonded to the back substrate surface 3 and FIG. 3B depicting a perspective view of the face 13 and the back 12 of the reinforcement strut 4.

According to these figures, the reinforcement strut 4 is implemented as a profile part and is produced, for example, from a metal plate by a metal forming process. The reinforcement strut 4 can be broken down, at least theoretically, into two sections 14, 16 with a V-shaped profile. Thus, the reinforcement strut 4 comprises a first V-shaped section 14 with two legs 15, 15′ positioned relative to each other at an acute angle that are connected to each other by a rear strip 17. The two legs 15, 15′ are in each case connected to a front strip 18 extending along the longitudinal sides 5 which is bent laterally from the respective leg 15, 15′. The two front strips 18 provide adhesive surfaces 19 for fastening the reinforcement strut 4 on the substrate 2. One of the two front strips 18 is connected to another leg 15″, which is positioned at an acute angle to the adjacent leg 15′, by which means, together with the adjacent leg 15′, a second V-shaped section 16 is formed, which is oriented in the opposite direction from the first V-shaped section. Another rear strip 17 is situated on this leg 15″. By means of the structure of the reinforcement strut 4 with an angled profile, the solar module 1 can be very effectively stiffened.

As illustrated in FIGS. 3A and 3B, an adhesive bead 20 is applied in each case on the two adhesive surfaces 19 of the reinforcement strut 4, which adhesive bead 20 serves for the adhesive bonding of the reinforcement strut 4 to the back substrate surface 3. The adhesive beads 20 extend substantially over the complete length of the adhesive surfaces 19. The adhesive beads 20 are made of an adhesive that is curable or cured in the bonded state, which cures, for example, in presence of oxygen, e.g., a two-component adhesive. Typically, the adhesive is, in the not cured state, soft or plastically malleable and is converted by curing into a hard state, optionally elastically malleable to a certain extent, with the reinforcement strut 4 fixedly bonded to the substrate 2.

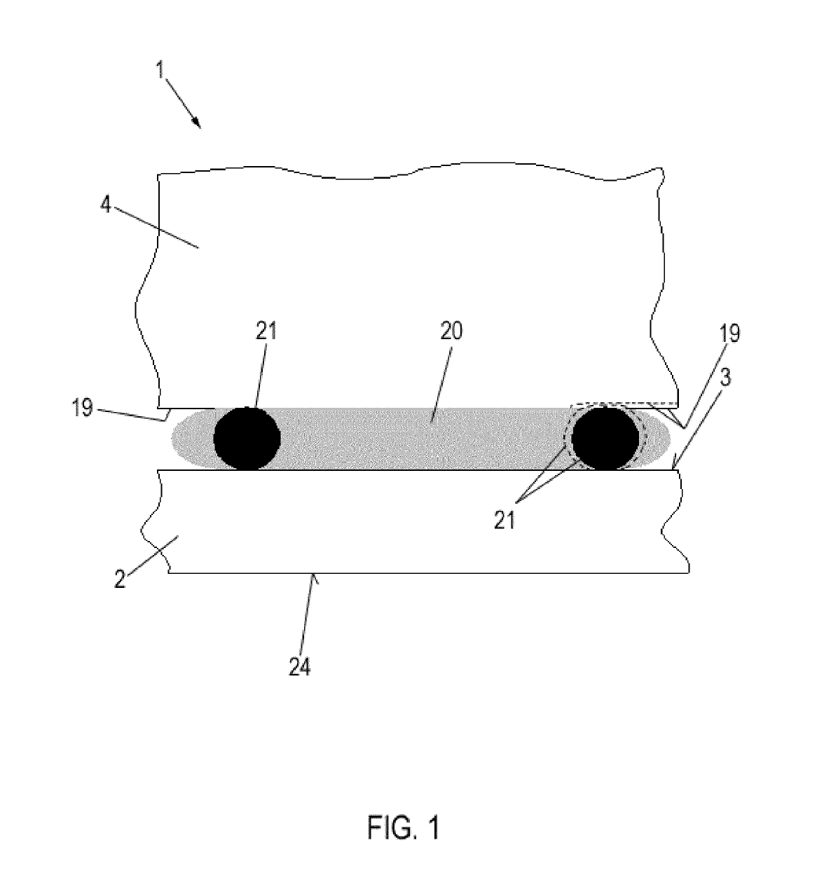

Reference is now made to FIG. 1, where the adhesive bonding of a reinforcement strut 4 to the back substrate surface 3 of the solar module is illustrated using a schematic (partial) cross-sectional representation along the longitudinal sides 5 of the solar module 1. The cross-section is cut through an adhesive bead 20.

According to this figure, two spacers 21, implemented here, for example, as spheres, are situated in the adhesive bead 20. By means of the, for example, equal diameters of the spacers 21, an equal minimum distance between the two adhesive surfaces 19 of the reinforcement strut 4 and the back substrate surface 3 can be pre-specified, when the reinforcement strut 4 is pressed against the substrate 2 for its adhesive bonding. As indicated in FIG. 1 on the right spacer 21, the spacers 21 can also have a different spherical diameter that is adapted to the local geometric conditions of the substrate 2 and/or the reinforcement strut 4. For example, the right spacer 21 (shown dashed in FIG. 1) can have a greater spherical diameter than the left spacer 21, in order to thus realize a greater distance between the substrate 2 and the reinforcement strut 4. This can be caused, for example, by an adhesive surface 19 of the reinforcement strut 4 (shown dashed in FIG. 1) set back relative to the back substrate surface 3. A different strength of compression of spacers 21 with an equal spherical diameter with the risk of point loading can be advantageously avoided by spacers 21 with a different spherical diameter.

Here, the spacers 21 are made, for example, from an elastically malleable plastic, for example, EPDM (ethylene-propylene-diene-rubber) with a Shore hardness of 85 or POM (polyoxymethylene) with a Shore hardness of 80. Thus, the spacers 21 are harder than the not cured adhesive in order to fulfill the spacer function but are not “too hard”, such that damage to the glass substrate 2 from local point loads can be avoided. Generally speaking, the hardness of the spacers 21 is less than that of the substrate 2. Moreover, the hardness of the spacers 21 corresponds at a maximum to that of the cured adhesive, in order to avoid point loads from the spacers 21 at the time of strong force effects in practice, for example, from snow or wind pressure loads. As depicted in FIG. 1, the spacers 21 are situated in each adhesive bead 20 on both sides of a transverse median plane 8 depicted in FIG. 4 near the transverse edge of the module 10. By means of the four spacers 21 per reinforcement strut 4, the minimum distance between the reinforcement strut 4 and the substrate 2 can be reliably and certainly maintained. The term “minimum distance” indicates that the distance between reinforcement strut 4 and substrate 2 can absolutely be greater but at least corresponds to the distance pre-specified by the spacers 21.

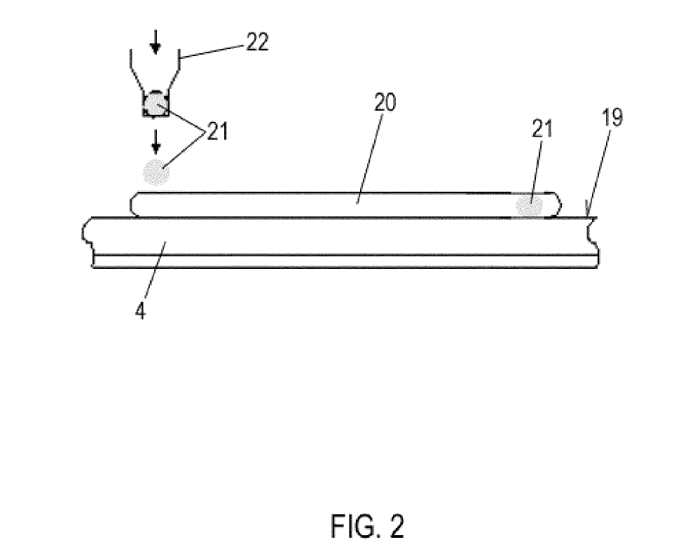

FIG. 2 illustrates the introduction of the spacers 21 into the respective adhesive bead 20. First, the adhesive bead 20 is applied on each of the two adhesive surfaces 19 of the reinforcement strut 4. This happens here, for example, by pressing the not yet cured adhesive through an adhesive nozzle (not shown) by pressurization. Then, the spherical spacers 21 are blown in pneumatically through a spacer nozzle 22 into the not yet cured adhesive bead 20, i.e., by air blast. This has the advantage that the adhesive nozzle does not have to be adapted to the dimensions of the spacers 21. The spacer nozzle 22 can, for example, be supplied from a central stock (not shown) with spacers 21 such that a simple charging of the spacer nozzle 20 [sic] as well as filling of the central stock is enabled. The spacer nozzle 22 can be arranged in the production, for example, near the adhesive nozzle. The adhesive bead 20 and the spacer nozzle 20 [sic] are movable relative to each other such that the spacers 21 can be selectively positioned within the adhesive bead 20. It is understood that the spacers 21 can equally be set in motion in another manner instead of by pneumatic pressurization.

Then, the reinforcement strut 4 preprocessed in this manner can be pressed with not yet cured adhesive against the rear substrate surface 3 and pressed on until the adhesive is cured. During this time, by means of the spacers 21, a minimum distance pre-specified by their diameters is maintained between the reinforcement strut 4 and the substrate 2. Since the solar module 1 is moved in industrial series production along the longitudinal sides 5, the spacers 21 are not displaced out of the adhesive bead 20 during transport of the solar module 1. The two reinforcement struts 4 can thus be bonded at a minimum distance from the substrate surface 3 on the substrate 2. As is clear from the preceding description, the invention makes available a frameless solar module that enables simple, reliable, and economical adhesive bonding of module carriers for supporting fastening on a module holder. The module carrier can be bonded on at a pre-specifiable minimum distance from the back substrate surface, for which purpose space holders or distance holders (spacers) are introduced into the not yet cured adhesive.

Further characteristics of the invention emerge from the following description:

A frameless solar module having a substrate and a cover layer, between which a layer structure for forming von solar cells is situated, wherein at least one module carrier for reinforcing and/or supporting mounting of the solar module is fastened on a substrate surface facing away from the layer structure, which carrier has at least one adhesive surface, which is adhesively bonded to the substrate surface by an adhesive layer made of a cured adhesive, wherein the adhesive layer includes one or a plurality of spacers, which are each case implemented to maintain the adhesive surface at a pre-specifiable minimum distance from the substrate surface when the adhesive of the adhesive layer is not cured.

In one embodiment, the spacers have a hardness that is less than the hardness of the substrate. In one embodiment, the spacers are made from an elastically malleable material. In one embodiment, the spacers have a hardness that is greater than that of the not cured adhesive of the adhesive layer and corresponds at a maximum to that of the cured adhesive of the adhesive layer. In one embodiment with a glass substrate, the elastically malleable material of the spacers has a Shore hardness in the range from 60 to 90 Shore, in particular 80 to 90 Shore. In one embodiment, the spacers are in each case implemented in a spherical shape. In one embodiment, the spacers have mutually different dimensions to maintain the distance between the adhesive surface of the module carrier and the substrate surface. In one embodiment with a rectangular shape, the at least one module carrier extends along the longitudinal sides and the at least one adhesive layer is implemented in the form of an adhesive bead extending along the longitudinal sides. In one embodiment, two module carriers extending along the longitudinal sides on both sides of a longitudinal median plane perpendicular to the substrate are fastened on the substrate surface, wherein the module carriers are in each case adhesively bonded to the substrate surface by at least one adhesive bead extending along the longitudinal sides, wherein the adhesive bead contains at least two spacers, which are situated on both sides of a transverse median plane arranged perpendicular to the substrate and perpendicular to the longitudinal median plane.

A method for producing a frameless solar module, with the following steps: providing a substrate and a cover layer, between which a layer structure for forming solar cells is situated; providing at least one module carrier for reinforcing and/or supporting mounting of the solar module; applying an adhesive layer made of a curable adhesive on at least one adhesive surface of the module carrier and/or a substrate surface facing away from the layer structure; introducing one or a plurality of spacers into the not yet cured adhesive, wherein the spacers are implemented in each case to maintain the adhesive surface at a pre-specifiable minimum distance from the substrate surface when the adhesive of the adhesive layer is not cured; bonding the module carrier to the substrate surface by means of the at least one adhesive layer; curing the adhesive of the adhesive layer for the adhesive fastening of the module carrier on the substrate.

In one embodiment, the spacers are introduced into the adhesive layer applied on the at least one adhesive surface of the module carrier and/or substrate surface. In one embodiment, the spacers are pneumatically blown into the adhesive layer by pressure surge. In one embodiment, the at least one module carrier extends along the longitudinal sides and the at least one adhesive layer is implemented in the form of an adhesive bead extending along the longitudinal sides. In one embodiment, two module carriers extending along the longitudinal sides on both sides of a longitudinal median plane perpendicular to the substrate are fastened on the substrate surface, wherein the module carriers are in each case adhesive bonded to the substrate surface by at least one adhesive bead extending along the longitudinal sides, wherein at least two spacers are introduced into the adhesive bead, which spacers are situated on both sides of a transverse median plane arranged perpendicular to the substrate and perpendicular to the longitudinal median plane.

The use of at least one adhesive layer made of a curable adhesive for fastening a module carrier on a substrate surface of a frameless solar module, wherein the adhesive layer contains one or a plurality of spacers, which are in each case implemented to maintain the module carrier at a pre-specifiable minimum distance from the substrate surface when the adhesive is not cured.

### LIST OF REFERENCE CHARACTERS

1 thin-film solar module
2 substrate
3 rear substrate surface
4 reinforcement strut
5 longitudinal side
6 transverse side
7 longitudinal median plane
8 transverse median plane
9 longitudinal edge of the module
10 transverse edge of the module
11 front
12 back
13 face
14 first V-shaped section
15, 15′, 15″ leg
16 second V-shaped section
17 rear strip
18 front strip
19 adhesive surface
20 adhesive bead
21 spacer
22 spacer nozzle
23 layer structure
24 front substrate surface
25 back electrode layer
26 semiconductor layer
27 buffer layer
28 front electrode layer
29 plastic layer
30 cover plate
31 solar cell
32 first trench
33 second trench
34 third trench

1. A frameless solar module having a substrate and a cover layer, between which a layer structure for forming solar cells is situated, comprising:
at least one module carrier for reinforcing and/or supporting mounting of the solar module, the module carrier being fastened on a substrate surface facing away from the layer structure, and has at least one adhesive surface which is adhesively bonded to the substrate surface by an adhesive layer made of a cured adhesive,
wherein:
the adhesive layer includes one or a plurality of spacers, which are in each case implemented to maintain the adhesive surface at a pre-specifiable minimum distance from the substrate surface when the adhesive of the adhesive layer is not cured, and
the spacers have mutually different dimensions for maintaining the distance between the adhesive surface of the module carrier and the substrate surface.

2. The frameless solar module according to claim 1, wherein the spacers have a hardness that is less than the hardness of the substrate.

3. The frameless solar module according to claim 2, wherein the spacers are made of an elastically malleable material.

4. The frameless solar module according to claim 3, wherein the spacers have a hardness that is greater than that of the not cured adhesive of the adhesive layer and corresponds at a maximum to that of the cured adhesive of the adhesive layer.

5. The frameless solar module with a glass substrate according to claim 4, wherein the elastically malleable material of the spacers has a Shore hardness in the range from 60 to 90 Shore, in particular 80 to 90 Shore.

6. The frameless solar module according to claim 1, wherein the spacers are implemented in each case with a spherical shape.

7. The frameless solar module with a rectangular shape according to claim 1, wherein the at least one module carrier extends along the longitudinal sides and the at least one adhesive layer is implemented in the form of an adhesive bead extending along the longitudinal sides.

8. The frameless solar module according to claim 7, wherein:
two module carriers extending along the longitudinal sides are fastened on the substrate surface on both sides of a longitudinal median plane perpendicular to the substrate,
the module carriers are in each case adhesively bonded to the substrate surface by at least one adhesive bead extending along the longitudinal sides, and
the adhesive bead contains at least two spacers that are situated on both sides of a transverse median plane arranged perpendicular to the substrate and perpendicular to the longitudinal median plane.

9. A method for producing a frameless solar module, comprising the following steps:
providing a substrate and a cover layer, between which a layer structure for forming solar cells is situated,
providing at least one module carrier for reinforcing and/or supporting mounting of the solar module,
applying an adhesive layer made of a curable adhesive on at least one adhesive surface of the module carrier and/or a substrate surface facing away from the layer structure,
introducing one or a plurality of spacers into the not yet cured adhesive, wherein the spacers are implemented in each case to maintain the adhesive surface at a pre-specifiable minimum distance from the substrate surface when the adhesive of the adhesive layer is not cured, and wherein the spacers are pneumatically blown into the adhesive layer by pressure surge,
bonding the module carrier to the substrate surface by means of the at least one adhesive layer, and
curing the adhesive of the adhesive layer for the adhesive fastening of the module carrier on the substrate.

10. The method according to claim 9, wherein the spacers are introduced into the adhesive layer applied on the at least one adhesive surface of the module carrier and/or the substrate surface.

11. The method for producing a solar module in a rectangular shape according to claim 9, wherein the at least one module carrier extends along the longitudinal sides and the at least one adhesive layer is implemented in the form of an adhesive bead extending along the longitudinal sides.

12. The method according to claim 11, wherein two module carriers extending along the longitudinal sides are fastened on the substrate surface on both sides of a longitudinal median plane perpendicular to the substrate, wherein the module carriers are in each case adhesively bonded to the substrate surface by at least one adhesive bead extending along the longitudinal sides, wherein at least two spacers are introduced into the adhesive bead, which spacers are situated on both sides of a transverse median plane arranged perpendicular to the substrate and perpendicular to the longitudinal median plane.

13. Use of at least one adhesive layer made of a curable adhesive for fastening a module carrier on a substrate surface of a frameless solar module, wherein the adhesive layer contains one or a plurality of spacers, which are in each case implemented to maintain the module carrier at a pre-specifiable minimum distance from the substrate surface when the adhesive is not cured, wherein the spacers have mutually different dimensions for maintaining the distance between the adhesive surface of the module carrier and the substrate surface.
